(19) United States
(12) Patent Application Publication
(10) Pub. No.: US 2018/0104827 A1
(43) Pub. Date: Apr. 19, 2018

(54) SUBSTRATE TRANSFER ROBOT AND END EFFECTOR OF SUBSTRATE TRANSFER ROBOT

(71) Applicant: KAWASAKI JUKOGYO KABUSHIKI KAISHA, Kobe-shi, Hyogo (JP)

(72) Inventors: Hirohiko GOTO, Akashi-shi (JP); Kenji SUGIYAMA, Urayasu-shi (JP)

(73) Assignee: KAWASAKI JUKOGYO KABUSHIKI KAISHA, Kobe-shi, Hyogo (JP)

(21) Appl. No.: 15/566,735

(22) PCT Filed: Apr. 6, 2016
(86) PCT No.: PCT/JP2016/001920

§ 371 Date: Oct. 16, 2017

(30) Foreign Application Priority Data
Apr. 15, 2015 (JP) 2015-083030

(51) Int. Cl. B25J 15/00; H01L 21/687; B25J 15/06

(52) U.S. Cl. CPC B25J 15/0061; B25J 15/0616; B25J 15/0033; H01L 21/68707

(57) ABSTRACT

An end effector of a substrate transfer robot includes a plurality of blades, a blade support section which supports the plurality of blades in such a manner that a gap between the plurality of blades in a substrate perpendicular direction is variable, and a blade drive unit which moves at least one of the plurality of blades in the substrate perpendicular direction relative to another blade of the plurality blades. Each of the plurality of blades includes a first primary surface facing a first side in the substrate perpendicular direction, a second primary surface which is on an opposite side to the first primary surface, a first substrate retaining mechanism which retains the substrate on the first primary surface, and a second substrate retaining mechanism which retains the substrate on the second primary surface.

### TECHNICAL FIELD

The present invention relates to a substrate transfer robot which transfers substrates such as semiconductor substrates or glass substrates, and an end effector of the substrate transfer robot.

### BACKGROUND ART

Conventionally, a substrate transfer robot is used to transfer (carry) a substrate with a thin plate shape such as a semiconductor substrate which is the material of a semiconductor device or a glass substrate which is the material of a liquid crystal display panel. The substrate transfer robot includes a robot arm, and an end effector mounted on a wrist of the robot arm. The end effector used to transfer the substrate includes, for example, a blade with a thin plate fork shape, and a substrate retaining mechanism which retains the substrate on the blade.

For example, the above-described substrate transfer robot performs operations for carrying the substrate into a treatment room and carrying the treated substrate out of the treatment room. As an example of such transfer operations, there is an operation for transferring the substrate to a cleaning room. In this case, if the same constituent of one end effector supports (holds) the substrate attached with contaminations, which is to be carried into the cleaning room, and the cleaned substrate which has been carried out of the cleaning room, the substrate may be re-contaminated by the contaminations which have come off the end effector.

To avoid this, the substrate transfer robot is required to change the use status of the end effector between a carry-in operation and a carry-out operation. To this end, it is proposed in a conventional technique that one end effector is provided with constituents for supporting (holding) a plurality of substrates, and the constituent supporting the substrate during the carry-in operation is different from the constituent supporting the substrate during the carry-out operation. Patent Literature 1 discloses that the end effector includes a first suction pad and a second suction pad, only the first suction pad suctions the substrate during the carry-in operation, and only the second suction pad suctions the substrate during the carry-out operation. Patent Literature 2 discloses that the end effector is provided with a rotary shaft including a plurality of substrate retaining sections on its periphery, and the rotary shaft is rotated after the substrate is carried into a treatment room so that the substrate is retained during the carry-out operation by a substrate retaining section different from that used during the carry-in operation.

### CITATION LIST

### Patent Literature

Patent Literature 1: Japanese-Laid Open Patent Application Publication No. Hei. 10-316242

Patent Literature 2: Japanese-Laid Open Patent Application Publication No. 2012-130985

### SUMMARY OF INVENTION

### Technical Problem

The above-described substrate transfer robot is required to further increase throughput (processing ability per unit time). To this end, for example, a plurality of substrates may be transferred (carried) by one-cycle operation of the robot.

The present invention has been developed in view of the above-described circumstances, and an object of the present invention is to provide a substrate transfer robot which can change the use status of constituents of one end effector which support (hold) substrates, depending on a case, and can increase throughput, and the end effector of the substrate transfer robot.

### Solution to Problem

According to one aspect of the present invention, there is provided an end effector mounted on a robot arm of a substrate transfer robot, the end effector comprising: a plurality of blades; a blade support section which supports the plurality of blades in such a manner that a gap between the plurality of blades in a substrate perpendicular direction is variable, in a case where the substrate perpendicular direction is defined as a direction perpendicular to a primary surface of a substrate retained by at least one of the plurality of blades; and a blade drive unit which moves at least one of the plurality of blades in the substrate perpendicular direction relative to another blade of the plurality blades, wherein each of the plurality of blades includes a first primary surface facing a first side in the substrate perpendicular direction, a second primary surface which is on an opposite side to the first primary surface, a first substrate retaining mechanism which retains the substrate on the first primary surface, and a second substrate retaining mechanism which retains the substrate on the second primary surface.

According to another aspect of the present invention, a substrate transfer robot comprises the above-described end effector; and a robot arm on which the end effector is mounted.

In accordance with the present invention, the substrates can be retained by the primary (main) surfaces of the blades. This makes it possible to transfer the plurality of substrates by one-cycle operation of the substrate transfer robot, and increase throughput in a work. Further, the use status of the constituents of one hand which support (hold) the substrates can be changed depending on a case in such a manner that clean substrates are retained on the first primary surfaces of the blades and contaminated substrates are retained on the second primary surfaces of the blades, for example.

### Advantageous Effects of Invention

In accordance with the present invention, it becomes possible to provide a substrate transfer robot which can change the use status of constituents of one end effector which support (hold) substrates, depending on a case, and can increase throughput, and the end effector of the substrate transfer robot.

### BRIEF DESCRIPTION OF DRAWINGS

FIG. 1 is a perspective view showing the overall configuration of a substrate transfer robot according to an embodiment of the present invention.

FIG. 2 is a side view of the substrate transfer robot.

FIG. 3 is a view showing the configuration of a control system of the substrate transfer robot.

FIG. 4 is a perspective view of an end effector.

FIG. 5 is a side view showing blades of the end effector and constituents which are in the vicinity of the blades.

FIG. 6A is a view showing a use status of the end effector for transferring (carrying) substrates, for explaining how two clean substrates are transferred.

FIG. 6B is a view showing a use status of the end effector for transferring substrates, for explaining how two contaminated substrates are transferred.

FIG. 6C is a view showing a use status of the end effector for transferring substrates, for explaining how the clean substrate and the contaminated substrate are transferred.

FIG. 7 is a view showing an example of a substrate retaining mechanism of an edge gripping type which can grip the substrate from above.

FIG. 8 is a perspective view of an end effector according to Modified Example 1.

FIG. 9 is a side view showing blades of the end effector according to Modified Example 1 and constituents which are in the vicinity of the blades.

FIG. 10A is a view showing a use status of the end effector according to Modified Example 1, for explaining how two clean substrates are transferred.

FIG. 10B is a view showing a use status of the end effector according to Modified Example 1, for explaining how two contaminated substrates are transferred.

FIG. 10C is a view showing a use status of the end effector according to Modified Example 1, for explaining how the clean substrate and the contaminated substrate are transferred.

FIG. 11A is a side view showing blades of an end effector according to Modified Example 2 and constituents which are in the vicinity of the blades.

FIG. 11B is a side view showing the blades of the end effector according to Modified Example 2 and the constituents which are in the vicinity of the blades.

FIG. 12A is a side view showing blades of an end effector according to Modified Example 3 and constituents which are in the vicinity of the blades.

FIG. 12B is a side view showing the blades of the end effector according to Modified Example 3 and the constituents which are in the vicinity of the blades.

FIG. 13 is a side view showing blades of an end effector according to Modified Example 4 and constituents which are in the vicinity of the blades.

FIG. 14 is a side view showing blades of an end effector according to Modified Example 5 and constituents which are in the vicinity of the blades.

FIG. 15 is a plan view of three blades.

### DESCRIPTION OF EMBODIMENTS

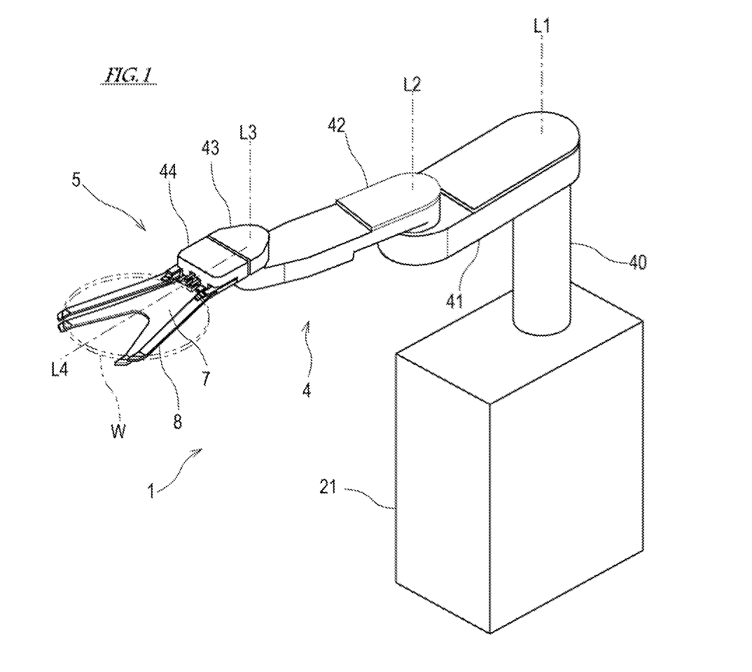

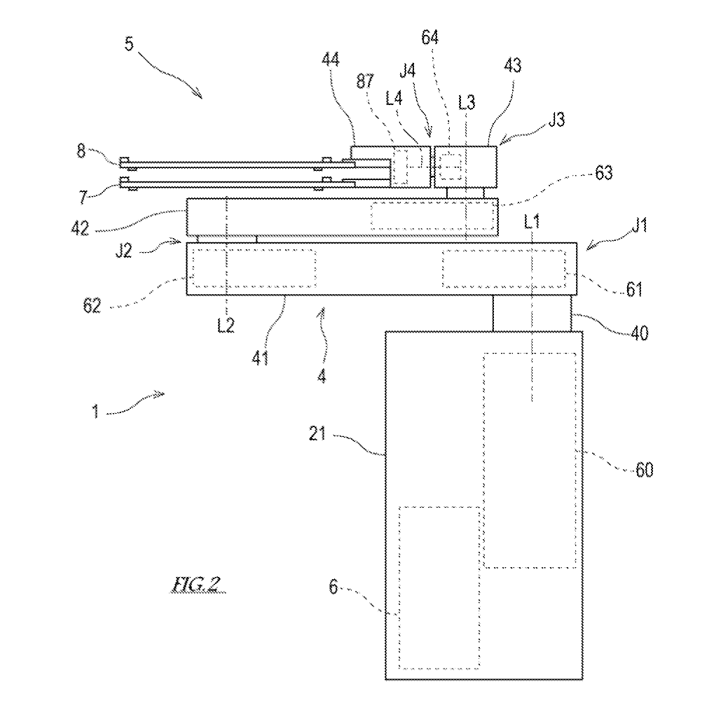

Next, the embodiment of the present invention will be described with reference to the drawings. FIG. 1 is a perspective view showing the overall configuration of a substrate transfer robot 1 according to an embodiment of the present invention. FIG. 2 is a side view of the substrate transfer robot 1. As shown in FIGS. 1 and 2, the substrate transfer robot 1 according to the embodiment of the present invention includes a robot arm 4, a robot hand 5 (hereinafter will be simply referred to as “hand 5” in some cases) as an example of an end effector for transferring substrates, the robot hand 5 being mounted on the tip end portion of the wrist of the robot arm 4, and a control unit 6 which controls the operation of the robot arm 4. Hereinafter, the constituents and members of the substrate transfer robot 1 will be described in detail.

Initially, the robot arm 4 will be described. The robot arm 4 according to the present embodiment is configured as a horizontal multi-joint (articulated) robot supported on a base 21. The robot arm 4 is not limited to the horizontal multi-joint robot and may be a vertical multi-joint robot.

The robot arm 4 includes an up-down shaft 40 extending upward from the base 21, a first link 41 coupled to the up-down shaft 40 via a first joint J1, a second link 42 coupled to the tip end portion of the first link 41 via a second joint J2, and a third link 43 coupled to the tip end portion of the second link 42 via a third joint J3. A blade support section 44 of the hand 5 is coupled to the tip end portion of the third link 43 via a fourth joint J4. An assembly unit including the third joint J3, the third link 43, and the fourth joint J4, which are mutually connected to each other, constitute the wrist of the robot arm 4.

A first axis L1 which is the rotational axis of the first joint 41, a second axis L2 which is the rotational axis of the second joint J2, and a third axis L3 which is the rotational axis of the third joint J3 extend substantially in a vertical direction. A fourth axis L4 which is the rotational axis of the fourth joint L4 extends substantially in a horizontal direction.

FIG. 3 is a view showing the configuration of a control system of the substrate transfer robot 1. As shown in FIGS. 2 and 3, an up-down drive unit 60 moves up and down or extends and contracts the up-down shaft 40 substantially in the vertical direction. The up-down drive unit 60 includes a servo motor M0, a position detector E0, a driving force transmission mechanism D0 which transmits a driving force of the servo motor M0 to the up-down shaft 40, and the like.

The first to fourth joints J1 to J4 are provided with first to fourth joint drive units 61 to 64, respectively, to rotate the joints J1 to J4 around their rotational axes. Each of the first to fourth joint drive units 61 to 64 includes corresponding one of servo motors M1 to M4, corresponding one of position detectors E1 to E4, corresponding one of driving force transmission mechanisms D1 to D4 which transmit driving forces of the servo motors M1 to M4 to the corresponding links, respectively, and the like. Each of the driving force transmission mechanisms D1 to D4 is, for example, a gear driving force transmission mechanism including a speed reduction unit. Each of the position detectors E0 to E4 is constituted by, for example, a rotary encoder. The servo motors M0 to M4 can operate independently of each other. When each of the servo motors M0 to M4 is driven, the corresponding one of the position detectors E0 to E4 detects a rotation position of an output shaft of the corresponding one of the servo motors M0 to M4.

The operation of the robot arm 4 is controlled by a control unit 6. As shown in FIG. 3, the control unit 6 includes a controller 30, and servo amplifiers A0 to A4 corresponding to the servo motors M0 to M4, respectively. The control unit 6 performs a servo control for moving the hand 5 mounted on the wrist of the robot arm 4 to a desired pose (position and posture in a space) along a desired path.

The controller 30 is a computer. The controller 30 includes, for example, a processor (not shown) such as a microcontroller, CPU, MPU, PLC, DSP, ASIC or FPGA, and a memory section (not shown) such as ROM or RAM. Programs to be executed by the processor, fixed data, etc., are stored in the memory section. In addition, teaching point data used to control the operation of the robot arm 4, data relating to the shape and dimension of the robot hand 5, data relating to the shape and dimension of a substrate W retained by the robot hand 5, etc., are stored in the memory section. In the controller 30, the processor reads and executes software such as the programs stored in the memory section to perform processing for controlling the operation of the substrate transfer robot 1. The controller 30 may be configured in such a manner that a single computer performs each processing by a centralized control or a plurality of computers cooperatively perform each processing by a distributed control.

The controller 30 calculates a target pose of the hand 5 after a passage of a specified control time, based on a pose of the hand 5 corresponding to the rotation positions detected by the position detectors E0 to E4, and the teaching point data stored in the memory section. The controller 30 outputs control commands (position commands) to the servo amplifiers A0 to A4, respectively so that the hand 5 takes the target pose after a passage of the specified control time. The servo amplifiers A0 to A4 supply drive currents to the servo motors M0 to M4, respectively, in response to the control commands. In this way, the hand 5 can be moved to take the desired pose.

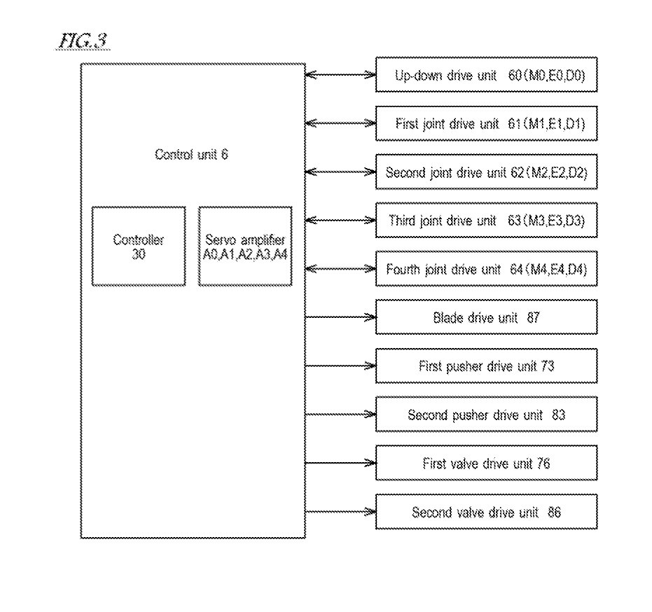

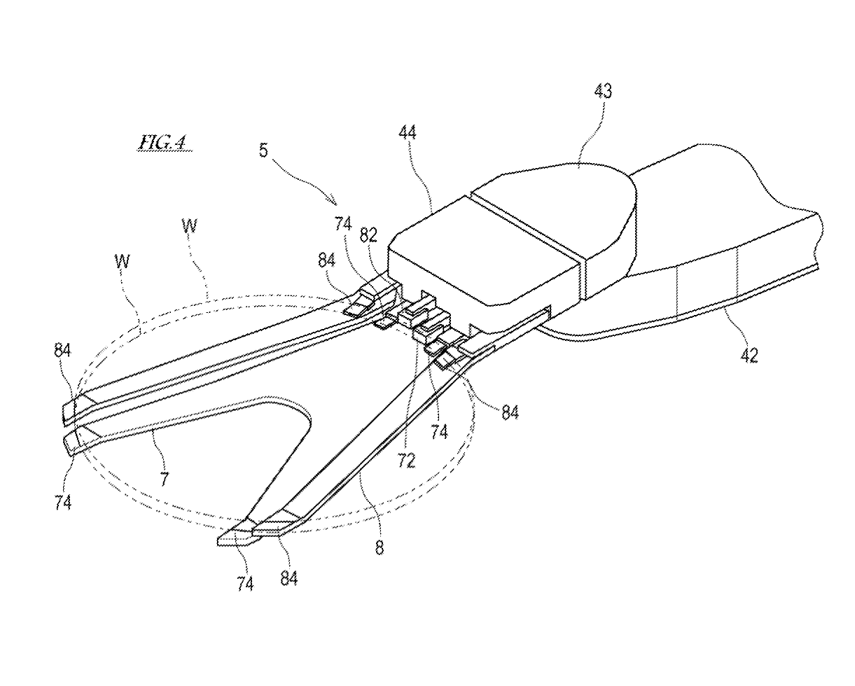

Next, the hand 5 which is the end effector of the substrate transfer robot 1 will be described in detail. FIG. 4 is a perspective view of the end effector. FIG. 5 is a side view showing blades of the end effector and constituents which are in the vicinity of the blades.

As shown in FIGS. 4 and 5, the hand 5 includes a blade support section 44, and two blades 7, 8 supported by the blade support section 44. One of the two blades is a fixed blade 7 whose position is fixed relative to the blade support section 44. The other of the two blades is a movable blade 8 which is movable in a substrate perpendicular direction Z relative to the blade support section 44 (and the fixed blade 7). As defined herein, the substrate perpendicular direction Z is defined as a direction perpendicular to a primary surface of the substrate W retained by at least one of the plurality of blades 7, 8. In the present embodiment, the substrate perpendicular direction Z substantially conforms to the vertical direction.

The fixed blade 7 is a thin plate member with a fork shape having two forked tip end portions. The base end portion of the fixed blade 7 is fixed to a blade base section 71. The blade base section 71 is supported by the blade support section 44.

A first primary (main) surface 7A (upper surface in FIGS. 4 and 5) of the fixed blade 7 is provided with a first substrate retaining mechanism 7a for retaining the substrate W on the first primary surface 7A. The first substrate retaining mechanism 7a is the substrate retaining mechanism of an edge gripping type. The first substrate retaining mechanism 7a includes gripping elements 74, a pusher 72, a first pusher drive unit 73, and the like. The substrate retaining mechanism of the edge gripping type is configured to support (hold) the edge of the substrate W by a pressure applied from several points to allow the blade to retain the substrate W. The gripping elements 74 are provided on the tip end portion and base end portion of the first primary surface 7A of the fixed blade 7. The pusher 72 is provided on the upper portion of the fixed blade 7. The pusher 72 is configured to push the substrate W toward the gripping element 74 on the tip end portion. The first pusher drive unit 73 advances and retracts the pusher 72 in a direction parallel to a direction in which the base end portion and tip end portion of the fixed blade 7 are connected. The first pusher drive unit 73 is, for example, an actuator such as an air cylinder.

A second primary (main) surface 7B (lower surface in FIGS. 4 and 5) of the fixed blade 7 is provided with a second substrate retaining mechanism 7b for retaining the substrate W on the second primary surface 7B. The second substrate retaining mechanism 7b is the substrate retaining mechanism of a pressure reduction and suction type. The second substrate retaining mechanism 7b includes suction pads 75, a first valve drive unit 76, and the like. The substrate retaining mechanism of the pressure reduction and suction type is configured to suction the substrate W to the fixed blade 7 to retain the substrate W. The suction pads 75 are provided on the tip end portion and base end portion of the second primary surface 7B of the fixed blade 7. The suction pads 75 are connected to a negative pressure source (not shown) via tubes. A suction force generated by each of the suction pads 75 is switched in such a manner that the first valve drive unit 76 (see FIG. 3) opens and closes a valve (not shown) provided between the suction pad 75 and the negative pressure source. The control unit 6 controls the operation of the first pusher drive unit 73 and the operation of the first valve drive unit 76 (see FIG. 3).

The suction pads 75 are desirably disposed on the fixed blade 7 so that the suction pads 75 contact the peripheral portion of the primary surface of the substrate W. If contaminations (e.g., particles) adhering to the suction pads 75 fall in a case where the blade support section 44 is rotated around the fourth axis L4 and the second primary surface 7B of the fixed blade 7 faces downward, only the peripheral portion of the primary surface of the substrate W located below the suction pad 75 is contaminated. As a result, the contaminations do not spread over a wide area.

The movable blade 8 includes at least one thin plate member provided in the vicinity of the fixed blade 7. The fixed blade 7 and the movable blade 8 do not overlap with each other in a plan view. The base end portion of the movable blade 8 is fixed to a blade base section 81.

The blade base section 81 is supported by the blade support section 44 by a linear motion mechanism 88 extending in the substrate perpendicular direction Z. The linear motion mechanism 88 allows the movable blade 8 to be moved in the substrate perpendicular direction Z relative to the blade support section 44 and the fixed blade 7. In the present embodiment, the movable blade 8 is movable relative to the fixed blade 7 from a location at which the movable blade 8 is substantially coplanar (flush) with the movable blade 8 to a location which is apart at a predetermined distance in the substrate perpendicular direction Z from the fixed blade 7. A gap (distance) in the substrate perpendicular direction Z between the fixed blade 7 and the movable blade 8 in a state in which the movable blade 8 and the fixed blade 7 are apart from each other may be constant or may be adjustable in a stepwise manner or in a non-stepwise manner.

A blade drive unit 87 moves up and down the movable blade 8. The blade drive unit 87 includes, for example, a rod joined to the blade base section 81 and an actuator which advances and retracts the rod with respect to a cylinder. The control unit 6 controls the operation of the blade drive unit 87 (see FIG. 3).

A first primary (main) surface 8A (upper surface in FIGS. 4 and 5) of the movable blade 8 is provided with a first substrate retaining mechanism 8a for retaining the substrate W on the first primary surface 8A. The first substrate retaining mechanism 8a is the substrate retaining mechanism of the edge gripping type. The first substrate retaining mechanism 8a includes gripping elements 84, a pusher 82, a second pusher drive unit 83, and the like. The gripping elements 84 are provided on the tip end portion and base end portion of the first primary surface 8A of the movable blade 8. The pusher 82 is provided on the upper portion of the movable blade 8. The pusher 82 is configured to push the substrate W toward the gripping element 84 on the tip end portion. The second pusher drive unit 83 advances and retracts the pusher 82 in a direction parallel to a direction in which the base end portion and tip end portion of the movable blade 8 are connected to each other. The second pusher drive unit 83 is, for example, an actuator such as an air cylinder. The pusher 82 and the second pusher drive unit 83 are supported by a blade base section 81. The pusher 82 and the second pusher drive unit 83 are movable up and down together with movable blade 8, relative to the fixed blade 7.

A second primary (main) surface 8B (lower surface in FIGS. 4 and 5) of the movable blade 8 is provided with a second substrate retaining mechanism 8b for retaining the substrate W on the second primary surface 8B. The second substrate retaining mechanism 8b is the substrate retaining mechanism of a pressure reduction and suction type. The second substrate retaining mechanism 8b includes suction pads 85, a second valve drive unit 86, and the like. The suction pads 85 are provided on the tip end portion and base end portion of the second primary surface 8B of the movable blade 8. The suction pads 85 are desirably disposed on the movable blade 8 in such a manner that the suction pads 85 contact the peripheral portion of the primary surface of the substrate W. The suction pads 85 are connected to a negative pressure source (not shown) via tubes. A suction force generated by each of the suction pads 85 is switched in such a manner that the second valve drive unit 86 (see FIG. 3) opens and closes a valve (not shown) provided between the suction pad 85 and the negative pressure source. The control unit 6 controls the operation of the second pusher drive unit 83 and the operation of the second valve drive unit 86 (see FIG. 3).

In the hand 5 having the above-described configuration, the first and second primary surfaces of each of the fixed blade 7 and the movable blade 8 are provided with the substrate retaining mechanisms of the substrate W, respectively, and the substrate retaining mechanisms can operate independently of each other.

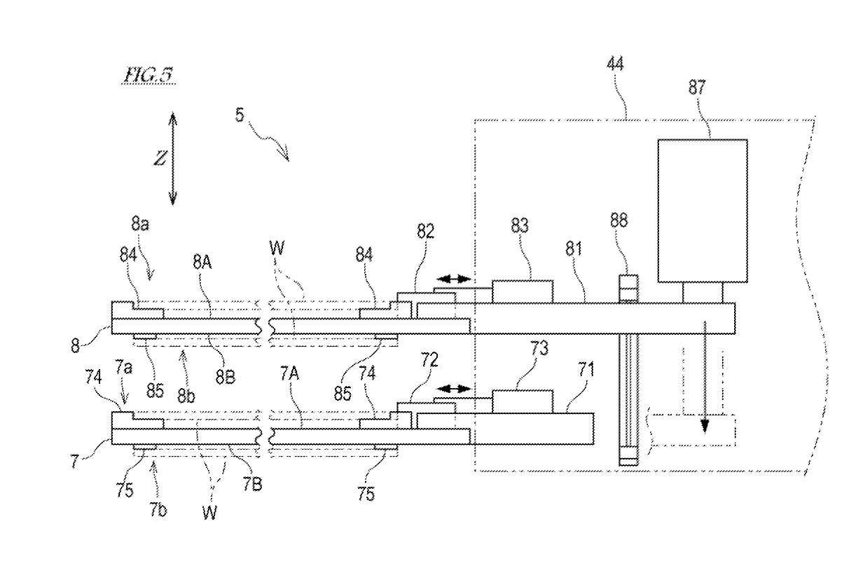

Next, the operation of the substrate transfer robot 1 will be described while paying an attention to the use statuses of the hand 5. FIGS. 6A, 6B, and 6C are views for explaining the use statuses of the end effector. FIG. 6A is a view for explaining how two clean substrates W₀ are transferred (carried). FIG. 6B is a view for explaining how two contaminated substrates W₁ are transferred. FIG. 6C is a view for explaining how the clean substrate W₀ and the contaminated substrate W₁ are transferred.

Initially, with reference to FIG. 6A, an example of the use status of the hand 5 in a case where the substrate transfer robot 1 transfers the two clean substrates W₀ will be described. In this case, the fixed blade 7 and the movable blade 8 of the hand 5 are apart from each other in the substrate perpendicular direction Z. Then, the substrates W₀ are placed on the first primary surface 7A of the fixed blade 7 and the first primary surface 8A of the movable blade 8, respectively. The substrates W₀ placed on the primary surfaces 7A, 8A are retained by the first substrate retaining mechanisms 7a, 8a, respectively. The substrate retaining mechanism 7a provided on the primary surface 7A of the fixed blade 7 and the substrate retaining mechanism 8a provided on the primary surface 8A of the movable blade 8 are the substrate retaining mechanisms of the edge gripping type. In a case where the substrate retaining mechanisms 7a, 8a of the edge gripping type are used, the constituents of the substrate retaining mechanisms, and the bodies of the fixed blade 7 and the movable blade 8 do not contact the primary surfaces of the clean substrates W₀.

Then, with reference to FIG. 6B, an example of the use status of the hand 5 in a case where the substrate transfer robot 1 transfers (carries) the two contaminated substrates W₁ will be described. In this case, the fixed blade 7 and the movable blade 8 of the hand 5 are apart from each other in the substrate perpendicular direction Z. In addition, the blade support section 44 is rotated substantially 180 degrees around the fourth axis L4. In this state, the hand 5 has a posture in which the second primary surface 7B of the fixed blade 7 and the second primary surface 8B of the movable blade 8 face upward.

Then, the substrates W₁ are placed on the second primary surface 7B of the fixed blade 7 and the second primary surface 8B of the movable blade 8, respectively. The substrates W₁ placed on the primary surfaces 7B, 8B are retained by the substrate retaining mechanisms 7b, 8b, respectively. The substrate retaining mechanism 7b provided on the second primary surface 7B of the fixed blade 7 and the substrate retaining mechanism 8b provided on the second primary surface 8B of the movable blade 8 are the substrate retaining mechanisms of the pressure reduction and suction type. In the substrate retaining mechanisms of the pressure reduction and suction type, the suction pads 75, 85 contact the primary surfaces of the substrates W₁, respectively. However, the contaminated substrates W₁ are to be carried into a cleaning room and cleaned there, from now. Therefore, even if the contaminated substrates W₁ are re-contaminated by the contaminations which have come off the suction pads 75, 85, this does not cause a problem.

Although in the examples of FIGS. 6A and 6B, each of the blades 7, 8 retains one substrate W, at least one of the blades 7, 8 may retain the substrates on both primary surfaces. In brief, the two blades 7, 8 are capable of retaining and transferring four substrates W at maximum at a time.

Then, with reference to FIG. 6C, an example of the use status of the hand 5 in a case where the substrate transfer robot 1 transfers (carries) the clean substrate We and the contaminated substrate W₁ will be described. In this case, the movable blade 8 is moved close to the fixed blade 7 to an equal level in the substrate perpendicular direction Z so that the first primary surface 7A of the fixed blade 7 and the first primary surface 8A of the movable blade 8 of the hand 5 become substantially coplanar with each other.

In a case where the fixed blade 7 and the movable blade 8 are used as a single blade as described above, the substrate retaining mechanism(s) of one or both of the fixed blade 7 and the movable blade 8 may operate.

For example, the clean substrate W₀ is placed on the first primary surface 7A of the fixed blade 7 and the first primary surface 8A of the movable blade 8, and the first substrate retaining mechanism 7a of the fixed blade 7 and/or the first substrate retaining mechanism 8a of the movable blade 8 retain(s) the substrate W₀. Also, for example, the second substrate retaining mechanism 7b of the fixed blade 7 and/or the second substrate retaining mechanism 8b of the movable blade 8 suction(s) and retain(s) the substrate W₁. Since the second substrate retaining mechanism 7b of the fixed blade 7 and the second substrate retaining mechanism 8b of the movable blade 8 are the substrate retaining mechanisms of the pressure reduction and suction type, the fixed blade 7 and the movable blade 8 can retain the substrate W1 even in a state in which the hand 5 has a posture in which the second primary surface 7B of the fixed blade 7 and the second primary surface 8B of the movable blade 8 face downward.

In the above-described operations, the hand 5 may firstly retain the contaminated substrate W₁ and then retain the clean substrate W₀. In the above-described operations, before the contaminated substrate W₁ is placed on the second primary surface 7B of the fixed blade 7, the hand 5 may be rotated substantially 180 degrees around the fourth axis L4 to change the posture of the fixed blade 7 so that the second primary surface 7B faces upward. Further, in the above-described operations, at least one of the clean substrate W₀ and the contaminated substrate W₁ may be retained on one or both of the first primary surface 7A of the fixed blade 7 and the second primary surface 7B of the fixed blade 7.

In the above-described operations, the substrate retaining mechanisms of the edge gripping type provided on the blades 7, 8 are configured to grip the substrates W from below. Alternatively, the substrate retaining mechanisms of the edge gripping type provided on the blades 7, 8 may be configured to grip the substrates W from above (may include the substrate retaining mechanism configured to grip the substrate from above and below).

In a case where the substrate retaining mechanism of the edge gripping type grips the substrate W from above, it is difficult to uniquely set the position of the substrate W with respect to the blade 7 in the substrate perpendicular direction Z, due to a warpage of the substrate W or a deviation of a teaching point. In view of this, to absorb the above-described position gap in the substrate perpendicular direction Z, of the substrate W with respect to the blade 7, a dimension of the gripping element 74 in the substrate perpendicular direction Z in the substrate retaining mechanism of the edge gripping type which can grip the substrate W from above is desirably larger than that in the substrate retaining mechanism of the edge gripping type which can grip the substrate W from below.

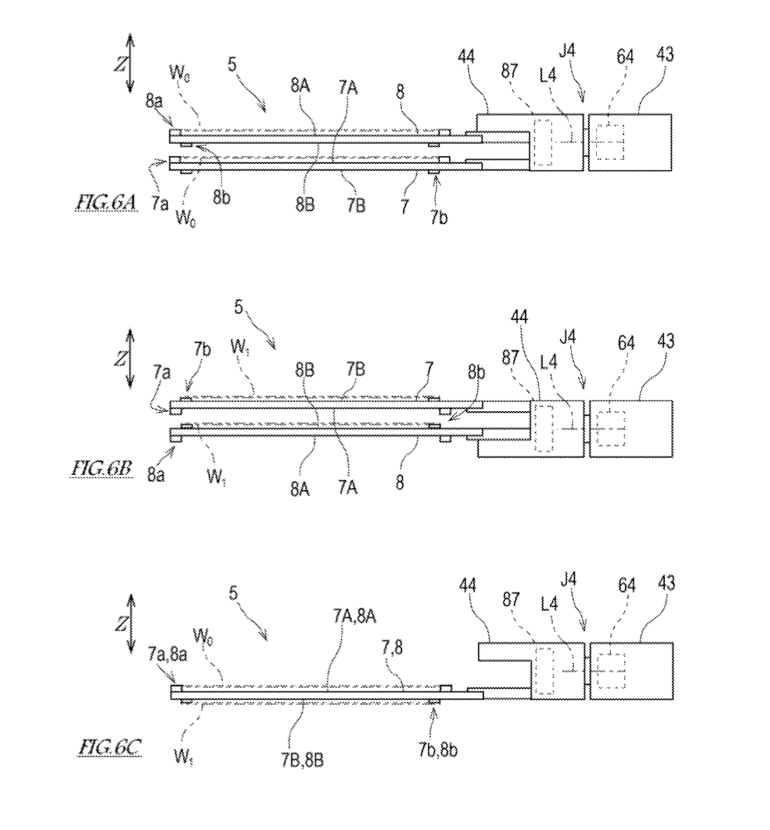

FIG. 7 is a view showing an example of the substrate retaining mechanism of the edge gripping type which can grip the substrate W from above. FIG. 7 shows a cross-section taken along a plane including the pusher 72 and the gripping element 74 on a tip end side. In the substrate retaining mechanism of the edge gripping type shown in FIG. 7, the gripping element 64 provided on the tip end side of the blade 7 and the pusher 72 are provided with protrusions (projections) protruding radially more inward than the edge of the retained substrate W. These protrusions serve to prevent the substrate W from being disengaged from the gripping element 74 in a state in which the primary surface retaining the substrate W faces downward.

As described above, of the substrate retaining mechanisms of the edge gripping type, the dimension of the gripping element 74 in the substrate perpendicular direction Z in the substrate retaining mechanism of the edge gripping type which can grip the substrate W from above is larger than that in the substrate retaining mechanism of the edge gripping type which can grip the substrate W from below. In view of this, the substrate retaining mechanism of the edge gripping type is provided on one of the primary surfaces 7A, 7B of the blade 7, and the substrate retaining mechanism of the pressure reduction and suction type is provided on the other of the primary surfaces 7A, 7B of the blade 7. In this configuration, the thickness of the blades 7, 8 including the substrate retaining mechanisms can be reduced.

As described above, the substrate transfer robot 1 according to the present embodiment includes the end effector, and the robot arm 4 on which the end effector is mounted. The hand 5 as the end effector includes the plurality of blades 7, 8, the blade support section 44 which supports (holds) the plurality of blades 7, 8 in such a manner that a gap (distance) between the plurality of blades 7, 8 in the substrate perpendicular direction Z is variable, and the blade drive unit 87 which moves at least one of the plurality of blades 7, 8 relative to another blade of the plurality of blades 7, 8 in the substrate perpendicular direction Z.

The plurality of blades 7, 8 include the first primary surfaces 7A, 8A facing a first side (one side) in the substrate perpendicular direction Z, the second primary surfaces 7B, 88B which are on the opposite side to the first primary surfaces 7A, 8A (on the opposite side or the other side of the blades 7, 8 with respect to the first primary surfaces 7A, 8A), the first substrate retaining mechanisms 7a, 8a which retain the substrates W on the first primary surfaces 7A, 8A, respectively, and the second substrate retaining mechanisms 7b, 8b which retain the substrates W on the second primary surfaces 7B, 8B, respectively.

In accordance with the substrate transfer robot 1 and the hand 5 as described above, the substrates W can be retained on the primary surfaces of the blades 7, 8. This makes it possible to transfer the plurality of substrates W by one-cycle operation of the robot 1, and increase throughput in a work. Further, the use status of the constituents of one hand 5 which support (hold) the substrates W can be changed in such a manner that the clean substrates W₀ are retained on the first primary surfaces 7A, 8A of the blades 7, 8, and the contaminated substrates W₁ are retained on the second primary surfaces 7B, 8B of the blades 7, 8, for example.

In the substrate transfer robot 1 and the hand 5 according to the above-described embodiment, one of the first substrate retaining mechanisms 7a, 8a, and the second substrate retaining mechanisms 7b, 8b (either the first substrate retaining mechanisms 7a, 8a or the second substrate retaining mechanisms 7b, 8b) are the substrate retaining mechanisms of the edge gripping type, including the plurality of gripping elements 74, 84 for gripping the substrates W and the pushers 72, 82, while the other of the first substrate retaining mechanisms 7a, 8a, and the second substrate retaining mechanisms 7b, 8b are the substrate retaining mechanisms of the pressure reduction and suction type, including at least one suction pads 75, 85 for suctioning the primary surfaces of the substrates W.

More specifically, in the above-described embodiment, the first primary surfaces 7A, 8A are the surfaces facing upward in a steady state, the first substrate retaining mechanisms 7a, 8a are the substrate retaining mechanisms of the edge gripping type, and the second substrate retaining mechanisms 7b, 8b are the substrate retaining mechanisms of the pressure reduction and suction type.

As described above, since each of the blades 7, 8 includes the substrate retaining mechanisms of different types provided on its primary surfaces, the thickness of the blades 7, 8 can be reduced. For example, in a case where the substrates W are carried into and out of a case (cassette) containing a plurality of substrates W arranged with specified gaps, the thickness of one blade and the substrate retaining mechanisms provided on one blade is required to be within the specified gap which is small. To this end, the substrate retaining mechanism of the pressure reduction and suction type is provided on at least one of the primary surfaces of each of the blades 7, 8. In this configuration, the thickness of the blades 7, 8 including the substrate retaining mechanisms can be reduced, compared to a case where the substrate retaining mechanisms of the edge gripping type are provided on the both primary surfaces of each of the blades 7, 8.

In the substrate transfer robot 1 according to the present embodiment, the robot arm 4 includes the rotational axis (fourth axis L4) around which at least a portion of the hand 5 is rotatable so that the first primary surfaces 7A, 8A of the blades 7, 8 face a second side (the other side) in the substrate perpendicular direction Z. Although in the above-described embodiment, this rotational axis (fourth axis AL4) is provided in the robot arm 4, it may be provided in the hand 5. Since the blades 7, 8 are rotatable around the fourth axis L4 in this way, the substrate retaining mechanisms of the edge gripping type or/and the pressure reduction and suction type are preferably used so that the primary surfaces facing downward can also retain the substrates W.

### Modified Example 1

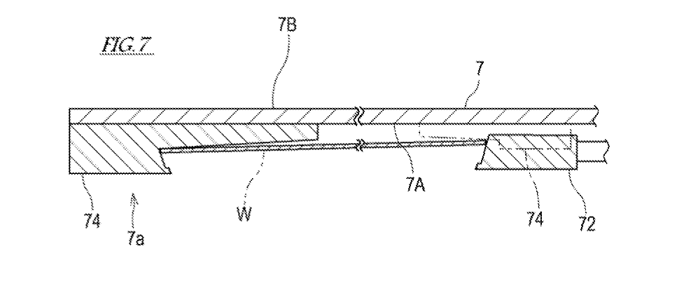

Next, Modified Example 1 of the above-described embodiment will be described. FIG. 8 is a perspective view of an end effector according to Modified Example 1. FIG. 9 is a side view showing blades of the end effector according to Modified Example 1 and constituents which are in the vicinity of the blades. In the following description of the present modified example, the same constituents as those of the above-described embodiment or the corresponding constituents are designated by the same reference symbols and will not be described in repetition in some cases.

As shown in FIGS. 8 and 9, the hand 5(5A) which is the end effector according to Modified Example 1 includes two blades which are the fixed blade 7 and the movable blade 8. The fixed blade 7 and the movable blade 8 include the first primary surfaces 7A, 8A facing a first side (one side) in the substrate perpendicular direction Z, the second primary surfaces 7B, 8B which are on the opposite side to the first primary surfaces 7A, 8A, the first substrate retaining mechanisms 7a, 8a which retain the substrates W on the first primary surfaces 7A, 8A, and the second substrate retaining mechanisms 7b, 8b which retain the substrates W on the second primary surfaces 7B, 8B. The first substrate retaining mechanism 7a of the fixed blade 7 is the substrate retaining mechanism of the pressure reduction and suction type. The second substrate retaining mechanism 7b of the fixed blade 7 is the substrate retaining mechanism of the edge gripping type. The first substrate retaining mechanism 8a of the movable blade 8 is the substrate retaining mechanism of the edge gripping type. The second substrate retaining mechanism 8b of the movable blade 8 is the substrate retaining mechanism of the pressure reduction and suction type.

Specifically, the hand 5A which is the end effector according to Modified Example 1 is different from the hand 5 according to the above-described embodiment in that the first substrate retaining mechanism 7a of the pressure reduction and suction type is provided on the first primary surface 7A of the fixed blade 7, and the second substrate retaining mechanism 7b of the edge gripping type is provided on the second primary surface 7B of the fixed blade 7. Except the above, the configuration of the hand 5A according to Modified Example 1 is the same as that of the hand 5 of the substrate transfer robot 1 according to the above-described embodiment.

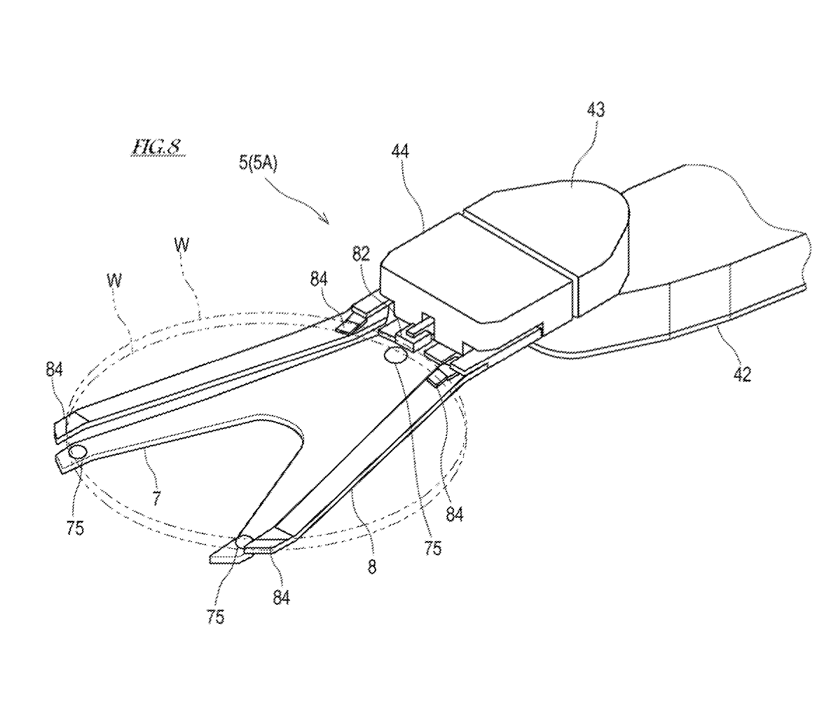

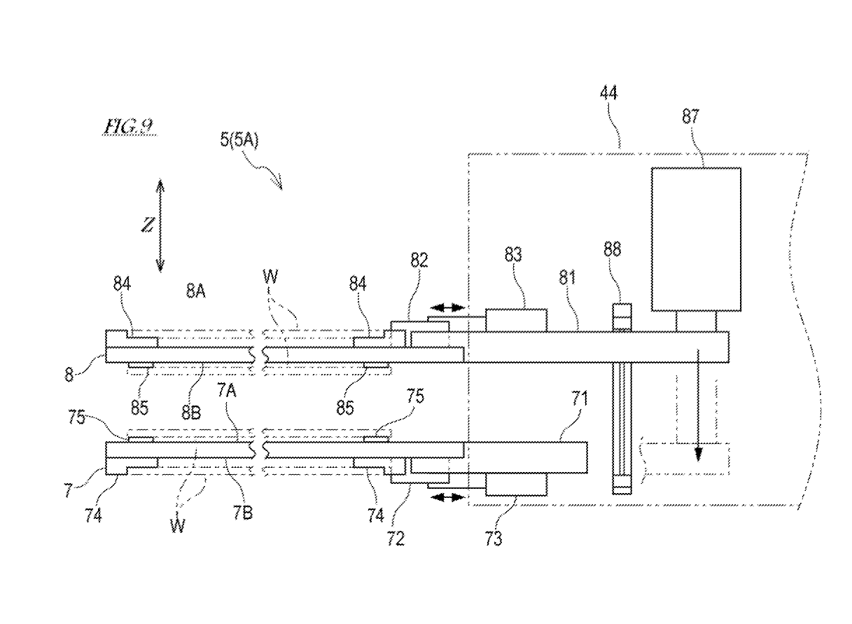

Next, the operation of the substrate transfer robot 1 having the above-described configuration will be described while paying an attention to the use statuses of the hand 5. FIGS. 10A, 10B, and 10C are views for explaining the use statuses of the end effector according to Modified Example 1. FIG. 10A is a view for explaining how two clean substrates W₀ are transferred. FIG. 10B is a view for explaining how two contaminated substrates W₁ are transferred. FIG. 10C is a view for explaining how the clean substrate W₀ and the contaminated substrate W₁ are transferred (carried).

Initially, with reference to FIG. 10A, an example of the use status of the hand 5A in a case where the substrate transfer robot 1 transfers (carries) two clean substrates W₀ will be described. In this case, the fixed blade 7 and the movable blade 8 of the hand 5A are apart from each other in the substrate perpendicular direction Z. Then, the substrate W₀ is placed on the first primary surface 8A of the movable blade 8, and the substrate W₀ placed on the primary surface 8A is retained by the first substrate retaining mechanism 8a. Then, the hand 5A is rotated substantially 180 degrees around the fourth axis LA. In this state, the hand 5A takes a posture in which the second primary surface 7B of the fixed blade 7 faces upward. Then, the substrate W₀ is placed on the second primary surface 7B of the fixed blade 7, and the substrate W₀ placed on the second primary surface 7B is retained by the substrate retaining mechanism 7b.

Then, with reference to FIG. 10B, an example of the use status of the hand 5A in a case where the substrate transfer robot 1 transfers (carries) the two contaminated substrates W₁ will be described. In this case, the fixed blade 7 and the movable blade 8 of the hand 5A are apart from each other in the substrate perpendicular direction Z. Then, the substrate W₁ is placed on the first primary surface 7A of the fixed blade 7, and the substrate W₁ placed on the first primary surface 7A is retained by the substrate retaining mechanism 7a. Then, the hand 5A is rotated substantially 180 degrees around the fourth axis L4. In this state, the hand 5A has a posture in which the second primary surface 7B of the fixed blade 7 faces upward. Then, the substrate W₁ is placed on the second primary surface 8B facing upward, of the movable blade 8, and the substrate W₁ placed on the second primary surface 8B is retained by the substrate retaining mechanism 8b.

Then, with reference to FIG. 10C, an example of the use status of the hand 5A in a case where the substrate transfer robot 1 transfers (carries) the clean substrate W₀ and the contaminated substrate W₁ will be described. In this case, the movable blade 8 is moved close to the fixed blade 7 to an equal level in the substrate perpendicular direction Z so that the first primary surface 7A of the fixed blade 7 and the first primary surface 8A of the movable blade 8 become substantially coplanar with each other.

Then, the clean substrate W₀ is placed on the first primary surface 7A of the fixed blade 7 and the first primary surface 8A of the movable blade 8, and the substrate retaining mechanism provided on at least one of the first primary surface 7A of the fixed blade 7 and the first primary surface 8A of the movable blade 8 retains the substrate W₀. Since the substrate W to be retained is the clean substrate W₀, it is desirable to selectively use the first substrate retaining mechanism 8a of the movable blade 8 which is the substrate retaining mechanism of the edge gripping type. Then, the substrate W₁ is retained on the second primary surface 7B of the fixed blade 7 and the second primary surface 8B of the movable blade 8. Since the substrate W to be retained is the contaminated substrate W₁, it is desirable to selectively use the substrate retaining mechanism provided on the second primary surface 8B of the movable blade 8 as the substrate retaining mechanism of the pressure reduction and suction type. This makes it possible to retain the substrate W on the second primary surface 7B of the fixed blade 7 and the second primary surface 8B of the movable blade 8 without rotating the hand 5A around the fourth axis LA.

As described above, in the hand 5A according to Modified Example 1, in a state in which the plurality of blades 7, 8 are apart from each other in the substrate perpendicular direction Z, the first substrate retaining mechanism 7a of the fixed blade 7 which is one of a set of blades 7, 8 which are adjacent to each other in the substrate perpendicular direction Z is the substrate retaining mechanism of the edge gripping type, and the first substrate retaining mechanism 8a of the blade 8 which is the other of the set of blades 7, 8 is the substrate retaining mechanism of the pressure reduction and suction type. Also, the second substrate retaining mechanism 7b of the fixed blade 7 which is one of the set of blades 7, 8 is the substrate retaining mechanism of the pressure reduction and suction type, and the second substrate retaining mechanism 8b of the blade 8 which is the other of the set of blades 7, 8 is the substrate retaining mechanism of the edge gripping type.

In the above-described configuration, in the set of blades 7, 8 which are adjacent to each other in the substrate perpendicular direction Z, the substrates W are retained by the substrate retaining mechanisms of the edge gripping type or the substrate retaining mechanisms of the pressure reduction and suction type. For example, the two the contaminated substrates W₁ are retained by the inner portions of the set of blades 7, 8 in the substrate perpendicular direction Z, and the two clean substrates W₀ can be retained by the outer portions of the set of blades 7, 8 in the substrate perpendicular direction Z. By using the blades 7, 8 in this way, it becomes possible to prevent a situation in which the clean substrate W₀ is re-contaminated by the contaminations or the like which has come off the contaminated substrate W₁.

### Modified Example 2

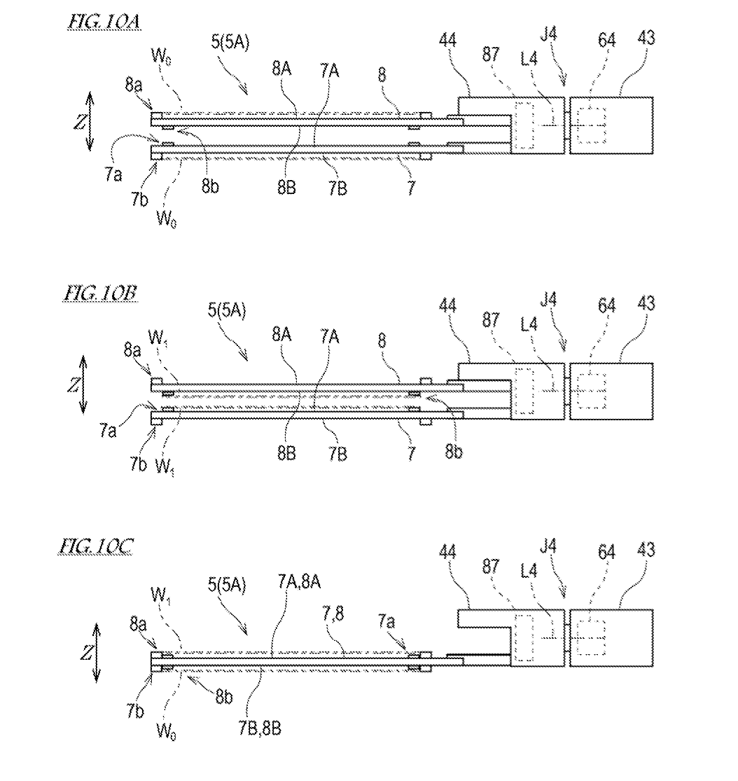

Next, Modified Example 2 of the above-described embodiment will be described. FIGS. 11A and 11B are side views showing blades of an end effector according to Modified Example 2 and constituents which are in the vicinity of the blades. In the following description of the present modified example, the same constituents as those of the above-described embodiment or the corresponding constituents are designated by the same reference symbols and will not be described in repetition in some cases.

As shown in FIGS. 11A and 11B, the hand 5(5B, 5B′) which is the end effector according to Modified Example 2 includes two blades which are the fixed blade 7 and the movable blade 8. The fixed blade 7 and the movable blade 8 include the first primary surfaces 7A, 8A facing a first side (one side) in the substrate perpendicular direction Z, the second primary surfaces 7B, 8B which are on the opposite side to the first primary surfaces 7A, 8A, the first substrate retaining mechanisms 7a, 8a which retain the substrates W on the first primary surfaces 7A, 8A, and the second substrate retaining mechanisms 7b, 8b which retain the substrates W on the second primary surfaces 7B, 8B. The first primary surfaces 7A, 8A are the surfaces facing upward in a steady state. The first substrate retaining mechanisms 7a, 8a are the substrate retaining mechanisms of a friction type. The second substrate retaining mechanisms 7b, 8b are the substrate retaining mechanisms of the pressure reduction and suction type or the edge gripping type. The second substrate retaining mechanisms 7b, 8b of the hand 5(5B) of FIG. 11A are the substrate retaining mechanisms of the pressure reduction and suction type. The second substrate retaining mechanisms 7b, 8b of the hand 5(5B′) of FIG. 11B are the substrate retaining mechanisms of the edge gripping type. The substrate retaining mechanism of the friction type includes at least one friction pad 95 for generating a friction between the friction pad 95 and the primary surface of the substrate W. In the present modified example, the friction pads 95 are provided on the tip end portion and base end portion, respectively, of each of the first primary surfaces 7A, 8A of the blades 7, 8.

In brief, the hand 5B according to Modified Example 2 is different from the hand 5 according to the above-described embodiment, in the type of the first substrate retaining mechanisms 7a, 8a and the second substrate retaining mechanisms 7b, 8b. Except the above, the configuration of the hand 5B according to Modified Example 2 is substantially the same as that of the hand 5 of the substrate transfer robot 1 according to the above-described embodiment.

### Modified Example 3

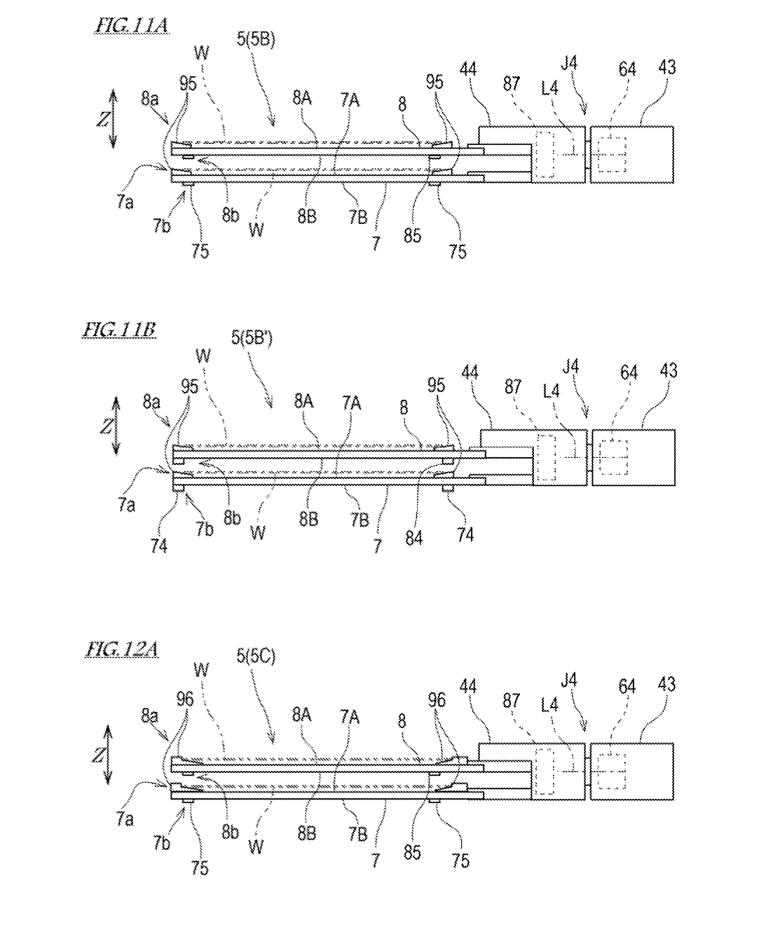

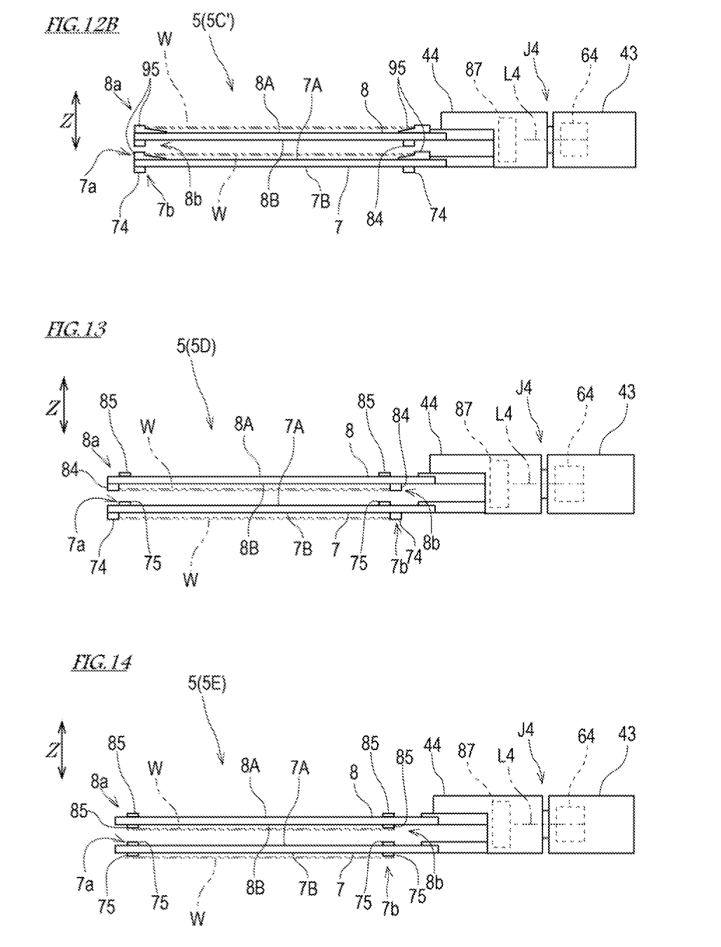

Next, Modified Example 3 of the above-described embodiment will be described. FIGS. 12A and 12B are side views showing blades of an end effector according to Modified Example 3 and constituents which are in the vicinity of the blades. In the following description of the present modified example, the same constituents as those of the above-described embodiment or the corresponding constituents are designated by the same reference symbols and will not be described in repetition in some cases.

As shown in FIGS. 12A and 12B, the hand 5(5C, 5C′) which is the end effector according to Modified Example 3 includes two blades which are the fixed blade 7 and the movable blade 8. The fixed blade 7 and the movable blade 8 include the first primary surfaces 7A, 8A facing a first side (one side) in the substrate perpendicular direction Z, the second primary surfaces 7B, 8B which are on the opposite side to the first primary surfaces 7A, 8A, the first substrate retaining mechanisms 7a, 8a which retain the substrates W on the first primary surfaces 7A, 8A, and the second substrate retaining mechanisms 7b, 8b which retain the substrates W on the second primary surfaces 7B, 8B. The first primary surfaces 7A, 8A are the surfaces facing upward in a steady state. The first substrate retaining mechanisms 7a, 8a are the substrate retaining mechanisms of a fitting type. The second substrate retaining mechanisms 7b, 8b are the substrate retaining mechanisms of the pressure reduction and suction type or the edge gripping type. The second substrate retaining mechanisms 7b, 8b of the hand 5(5C) of FIG. 12A are the substrate retaining mechanisms of the pressure reduction and suction type. The second substrate retaining mechanisms 7b, 8b of the hand 5(5C′) of FIG. 12B are the substrate retaining mechanisms of the edge gripping type. The substrate retaining mechanism of the fitting type includes at least one recessed (depressed) portion forming element 96 to which the substrate W is fittable. A recessed portion is formed on the primary surface of each of the blades 7, 8 by the recessed portion forming element 96. The substrate W is fitted into this recessed portion and retained by the blade. In the present modified example, the recessed portion forming elements 96 are provided on the tip end portion and base end portion of each of the first primary surfaces 7A, 8A of the fixed blade 7 and the movable blade 8.

In brief, the hands 5C, 5C′ according to Modified Example 3 are different from the hand 5 according to the above-described embodiment in the type of the first substrate retaining mechanisms 7a, 8a and the second substrate retaining mechanisms 7b, 8b. Except the above, the configurations of the hands 5C, 5C′ according to Modified Example 3 are substantially the same as that of the hand 5 of the substrate transfer robot 1 according to the above-described embodiment.

In the hands 5B, 5B′ according to the above-described Modified Example 2 and the hands 5C, 5C′ according to the above-described Modified Example 3, the hand 5 cannot be rotated around the fourth axis L4 in a state in which the substrates W are placed on the first primary surfaces 7A, 8A of the blades 7, 8. However, by rotating the hand 5 around the fourth axis L4 in a state in which the substrates W are not placed on the first primary surfaces 7A, 8A, both of the primary surfaces of each of the blades 7, 8 can be used to transfer the substrates W. The substrate retaining mechanism of the friction type and the substrate retaining mechanism of the fitting type have simple structures and can reduce the thickness in the substrate perpendicular direction Z, compared to the substrate retaining mechanism of the edge gripping type. As a result, the thickness of the blades including the substrate retaining mechanisms can be reduced.

### Modified Example 4

Next, Modified Example 4 of the above-described embodiment will be described. FIG. 13 is a side view showing blades of an end effector according to Modified Example 4 and constituents which are in the vicinity of the blades. In the following description of the present modified example, the same constituents as those of the above-described embodiment or the corresponding constituents are designated by the same reference symbols and will not be described in repetition in some cases.

As shown in FIG. 13, the hand 5(5D) which is the end effector according to Modified Example 4 includes two blades which are the fixed blade 7 and the movable blade 8. The fixed blade 7 and the movable blade 8 include the first primary surfaces 7A, 8A facing a first side (one side) in the substrate perpendicular direction Z, the second primary surfaces 7B, 8B which are on the opposite side to the first primary surfaces 7A, 8A, the first substrate retaining mechanisms 7a, 8a which retain the substrates W on the first primary surfaces 7A, 8A, and the second substrate retaining mechanisms 7b, 8b which retain the substrates W on the second primary surfaces 7B, 8B. The first primary surfaces 7A, 8A are the surfaces facing upward. The first substrate retaining mechanisms 7a, 8a are the substrate retaining mechanisms of the pressure reduction and suction type. The second substrate retaining mechanisms 7b, 8b are the substrate retaining mechanisms of the edge gripping type. The second substrate retaining mechanisms 7b, 8b are desirably the substrate retaining mechanisms of the edge gripping type, which can grip the substrate W from above.

In brief, the hand 5D according to Modified Example 4 is different from the hand 5 according to the above-described embodiment in that the first substrate retaining mechanisms 7a, 8a are the substrate retaining mechanisms of the pressure reduction and suction type and the second substrate retaining mechanisms 7b, 8b are the substrate retaining mechanisms of the edge gripping type. Except the above, the configuration of the hand 5D according to Modified Example 4 is substantially the same as that of the hand 5 of the substrate transfer robot 1 according to the above-described embodiment.

### Modified Example 5

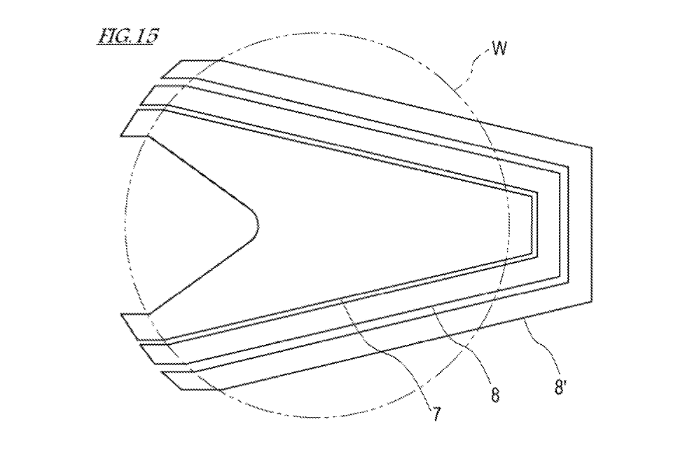

Next, Modified Example 5 of the above-described embodiment will be described. FIG. 14 is a side view showing blades of the end effector according to Modified Example 5 and constituents which are in the vicinity of the blades. In the following description of the present modified example, the same constituents as those of the above-described embodiment or the corresponding constituents are designated by the same reference symbols and will not be described in repetition in some cases.

As shown in FIG. 14, the hand 5(5E) which is the end effector according to Modified Example 5 includes two blades which are the fixed blade 7 and the movable blade 8. The blades 7, 8 include the first primary surfaces 7A, 8A facing a first side (one side) in the substrate perpendicular direction Z, the second primary surfaces 7B, 8B which are on the opposite side to the first primary surfaces 7A, 8A, the first substrate retaining mechanisms 7a, 8a which retain the substrates W on the first primary surfaces 7A, 8A, and the second substrate retaining mechanisms 7b, 8b which retain the substrates W on the second primary surfaces 7B, 8B. The first substrate retaining mechanisms 7a, 8a are the substrate retaining mechanisms of the pressure reduction and suction type, including at least one suction pad 75 and at least one suction pad 85, respectively. The second substrate retaining mechanisms 7b, 8b are the substrate retaining mechanisms of the pressure reduction and suction type, including at least one suction pad 75 and at least one suction pad 85, respectively.

In brief; the hand 5E according to Modified Example 5 is different from the hand 5 according to the above-described embodiment in that the first substrate retaining mechanisms 7a, 8a are the substrate retaining mechanisms of the pressure reduction and suction type Except the above, the configuration of the hand 5E according to Modified Example 5 is substantially the same as that of the hand 5 of the substrate transfer robot 1 according to the above-described embodiment.

Thus far, the preferred embodiment (and modified examples) of the present invention have been described. The above-described configurations can be changed as described below, for example.

Although in the above-described embodiment, the hand 5 includes the two blades which are the fixed blade 7 and the movable blade 8, the hand 5 may include three or more blades. FIG. 15 is a plan view of blades in a case where the hand 5 includes three or more blades. In the illustrated example, the hand 5 includes three blades which are the fixed blade 7, a first movable blade 8 provided outward of the fixed blade 7, and a second movable blade 8′ provided outward of the first movable blade 8. The three blades 7, 8, 8′ have a nested structure in which the first movable blade 8 and the fixed blade 7 are disposed inside the second movable blade 8′. When the blades 7, 8, 8′ are viewed in the substrate perpendicular direction Z, they do not overlap with each other. In other words, when the plurality of blades are viewed in the substrate perpendicular direction Z, they have a nested shape in which at least one blade is disposed inside another blade located on an outermost side.

In this structure, in a case where the plurality of blades are used in such a manner that they are apart from each other in the substrate perpendicular direction Z, a plurality of substrates W can be transferred (carried) by one-cycle operation of the substrate transfer robot 1. Therefore, throughput can be increased. In a case where the plurality of blades are made close to each other in the substrate perpendicular direction Z so that they are coplanar with each other, the thickness of the blades can be reduced like a single blade.

Although in the above-described embodiment, the outer blade is the movable blade 8 and the inner blade is the fixed blade 7, the inner blade may be the movable blade and the outer blade may be the fixed blade. Or, the two blades may be the movable blades. In brief, the hand 5 may be configured in any way so long as the gap (distance) in the substrate perpendicular direction Z between the plurality of blades is variable.

Although in the above-described embodiment, the first primary surface 7A of the fixed blade 7 and the first primary surface 8A of the movable blade 8 are substantially coplanar with each other (form the same flat surface) in a state in which the fixed blade 7 and the movable blade 8 are close to each other in the substrate perpendicular direction Z, the first primary surfaces 7A, 8A may not be substantially coplanar with each other so long as the whole thickness of the blades 7, 8 in the substrate perpendicular direction Z in the state in which the fixed blade 7 and the movable blade 8 are close to each other is substantially smaller than a predetermined dimension (e.g., pitch of a cassette in which the substrates are stored).

Numerous modifications and alternative embodiments of the present invention will be apparent to those skilled in the art in view of the foregoing description. Accordingly, the description is to be construed as illustrative only, and is provided for the purpose of teaching those skilled in the art the best mode of conveying out the invention. The details of the structure and/or function may be varied substantially without departing from the spirit of the invention.

### REFERENCE SIGNS LIST

1: substrate transfer robot
4: robot arm
5, 5A˜5E: robot hand (end effector)
6: control unit
7: fixed blade
7A: first primary surface
7B: second primary surface
7a: first substrate retaining mechanism
7b: second substrate retaining mechanism
8: movable blade
8A: first primary surface
8B: second primary surface
8a: first substrate retaining mechanism
8b: second substrate retaining mechanism
21: base
30: controller
40: up-down shaft
41˜43: link
44: blade support section
60: up-down drive unit
61˜64: joint drive unit
71, 81: blade base section
72, 82: pusher
73, 83: pusher drive unit
74, 84: gripping element
75, 85: suction pad
76, 86: valve drive unit
87: blade drive unit
88: linear motion mechanism
95: friction pad
96: recessed portion forming element
A0˜A4: servo amplifier
D0˜D4: driving force transmission mechanism
E0˜E4: position detector
J1˜J4: joint
L1˜L4: axis
M₀˜M₄: servo motor
W, W₀, W₁: substrate
Z: substrate perpendicular direction

1. An end effector mounted on a robot arm of a substrate transfer robot, the end effector comprising:
a plurality of blades;
a blade support section which supports the plurality of blades in such a manner that a gap between the plurality of blades in a substrate perpendicular direction is variable, in a case where the substrate perpendicular direction is defined as a direction perpendicular to a primary surface of a substrate retained by at least one of the plurality of blades; and
a blade drive unit which moves at least one of the plurality of blades in the substrate perpendicular direction relative to another blade of the plurality blades,
wherein each of the plurality of blades includes a first primary surface facing a first side in the substrate perpendicular direction, a second primary surface which is on an opposite side to the first primary surface, a first substrate retaining mechanism which retains the substrate on the first primary surface, and a second substrate retaining mechanism which retains the substrate on the second primary surface.

2. The end effector according to claim 1,
wherein one of the first substrate retaining mechanism and the second substrate retaining mechanism is a substrate retaining mechanism of an edge gripping type, including a plurality of elements for gripping an edge of the substrate, and a pusher, and
wherein the other of the first substrate retaining mechanism and the second substrate retaining mechanism is a substrate retaining mechanism of a pressure reduction and suction type, including at least one suction pad for suctioning the primary surface of the substrate.

3. The end effector according to claim 2,
wherein the first primary surface is a surface facing upward,
wherein the first substrate retaining mechanism is the substrate retaining mechanism of the edge gripping type, and
wherein the second substrate retaining mechanism is the substrate retaining mechanism of the pressure reduction and suction type.

4. The end effector according to claim 2,
wherein in a state in which the plurality of blades are apart from each other in the substrate perpendicular direction, the first substrate retaining mechanism of one of a set of blades adjacent to each other in the substrate perpendicular direction is the substrate retaining mechanism of the edge gripping type, and the first substrate retaining mechanism of the other of the set of blades is the substrate retaining mechanism of the pressure reduction and suction type.

5. The end effector according to claim 1,
wherein both of the first substrate retaining mechanism and the second substrate retaining mechanism are substrate retaining mechanisms of a pressure reduction and suction type, each including at least one suction pad for suctioning the primary surface of the substrate.

6. The end effector according to claim 1,
wherein the first primary surface is a surface facing upward,
wherein the first substrate retaining mechanism is a substrate retaining mechanism of a friction type, including at least one friction pad for generating a friction between the friction pad and the primary surface of the substrate, or a substrate retaining mechanism of a fitting type, including at least one recessed portion to which the substrate is fittable, and
wherein the second substrate retaining mechanism is a substrate retaining mechanism of a pressure reduction and suction type, including at least one suction pad for suctioning the primary surface of the substrate, or a substrate retaining mechanism of an edge gripping type, including a plurality of elements for gripping an edge of the substrate, and a pusher.

7. The end effector according to claim 2,
wherein the at least one suction pad is disposed on the first primary surface or the second primary surface in such a manner that the suction pad contacts a peripheral portion of the primary surface of the substrate.

8. The end effector according to claim 1,
wherein the plurality of blades have a nested shape in which at least one of the plurality of blades is disposed inside another blade located on an outermost side, when the plurality of blades are viewed in the substrate perpendicular direction.

9. A substrate transfer robot comprising:
the end effector as recited in claim 1; and
a robot arm on which the end effector is mounted.

10. The substrate transfer robot according to claim 9,
wherein the end effector or the robot arm has a rotational axis around which at least a portion of the end effector is rotatable so that the first primary surface faces a second side in the substrate perpendicular direction.
